(19) United States
(12) Patent Application Publication
(10) Pub. No.: US 2022/0347711 A1
(43) Pub. Date: Nov. 3, 2022

(54) SUBSTRATE PROCESSING APPARATUS AND SUBSTRATE PROCESSING METHOD

(71) Applicant: Tokyo Electron Limited, Tokyo (JP)

(72) Inventors: Tetsuya Sakazaki, Koshi City (JP); Katsuhiro Morikawa, Koshi City (JP)

(21) Appl. No.: 17/661,124

(22) Filed: Apr. 28, 2022

(30) Foreign Application Priority Data
Apr. 30, 2021 (JP) 2021-077562
Jan. 6, 2022 (JP) 2022-001222

(51) Int. Cl. B05C 5/00; B05C 13/02; B05C 5/02; B05D 1/00; B05D 1/02

(52) U.S. Cl. CPC B05C 5/001; B05C 13/02; B05C 5/0204; B05D 1/002; B05D 1/02

(57) ABSTRACT

A substrate processing apparatus includes a substrate holder, a processing liquid supply and a cover unit. The substrate holder holds a substrate horizontally and rotate the substrate. The processing liquid supply supplies a processing liquid toward a first surface of the substrate held by the substrate holder. The cover unit faces a second surface of the substrate, the second surface being opposite to the first surface. The cover unit includes a heater configured to heat the substrate. The cover unit is provided with an opening at a position corresponding to a central portion of the substrate and multiple gas supply openings, at an outer peripheral side than the opening, through which a gas is supplied toward the second surface of the substrate. The gas is heated by the heater. A supply amount of at least some of the gas is adjusted based on a rotation speed of the substrate.

### CROSS-REFERENCE TO RELATED APPLICATION

This application claims the benefit of Japanese Patent Application Nos. 2021-077562 and 2022-001222 filed on Apr. 30, 2021, and Jan. 6, 2022, respectively, the entire disclosures of which are incorporated herein by reference.

### TECHNICAL FIELD

The various aspects and embodiments described herein pertain generally to a substrate processing apparatus and a substrate processing method.

### BACKGROUND

Patent Document 1 describes supplying a processing liquid toward a rear surface of a substrate.
Patent Document 1: Japanese Patent Laid-open Publication No. 2016-143790

### SUMMARY

In one exemplary embodiment, a substrate processing apparatus includes a substrate holder, a processing liquid supply and a cover unit. The substrate holder is configured to hold a substrate horizontally and rotate the substrate. The processing liquid supply is configured to supply a processing liquid toward a first surface of the substrate held by the substrate holder. The cover unit is configured to face a second surface of the substrate, the second surface being opposite to the first surface. The cover unit includes a heater configured to heat the substrate. The cover unit is provided with an opening and multiple gas supply openings. The opening is provided at a position corresponding to a central portion of the substrate. The multiple gas supply openings supply, at an outer peripheral side than the opening, a gas toward the second surface of the substrate. The gas is heated by the heater. A supply amount of at least some of the gas is adjusted based on a rotation speed of the substrate.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a schematic configuration of a substrate processing system according to a first exemplary embodiment;

FIG. 2 is a schematic diagram illustrating a configuration of a processing unit according to the first exemplary embodiment;

FIG. 3 is a schematic diagram illustrating an arrangement of a pressure sensor and a plurality of temperature sensors in the processing unit according to the first exemplary embodiment;

FIG. 4 is a flowchart for describing a substrate processing according to the first exemplary embodiment;

FIG. 5 is a flowchart for describing an abnormality determination processing according to the first exemplary embodiment;

FIG. 6 is a schematic diagram illustrating a configuration of a processing unit according to a second exemplary embodiment;

FIG. 7 is a diagram illustrating a supply direction (discharge direction) of a N₂ gas discharged from third discharge openings according to the second exemplary embodiment;

FIG. 8 is a schematic diagram illustrating flows of a processing liquid, the N₂ gas, and so forth in the processing unit according the second exemplary embodiment; and

FIG. 9 is a diagram illustrating a supply direction (discharge direction) of the N₂ gas discharged from the third discharge openings according to a modification example of the second exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a substrate processing apparatus and a substrate processing method according to the present disclosure will be described in detail with reference to the accompanying drawings. However, it should be noted that the substrate processing apparatus and substrate processing method of the present disclosure are not limited by the following exemplary embodiments.

### First Exemplary Embodiment

<Outline of Substrate Processing System>

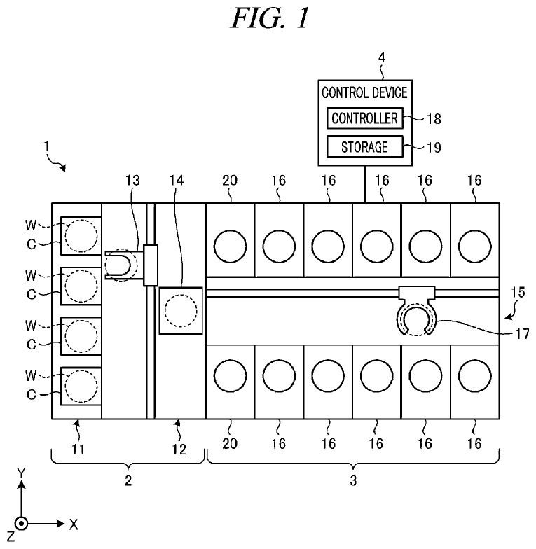

A schematic configuration of a substrate processing system 1 according to a first exemplary embodiment will be explained with reference to FIG. 1. FIG. 1 is a diagram illustrating the schematic configuration of the substrate processing system 1 according to the first exemplary embodiment. In the following description, to clarity positional relationship, the X-axis, the Y-axis and the Z-axis which are orthogonal to each other will be defined, and the positive Z-axis direction will be regarded as a vertically upward direction.

As depicted in FIG. 1, the substrate processing system 1 (an example of a substrate processing apparatus) includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, a plurality of carriers C is placed to accommodate a plurality of substrates, i.e., semiconductor wafers W (hereinafter, referred to as “wafers W”) in the exemplary embodiments horizontally.

The transfer section 12 is provided adjacent to the carrier placing section 11, and provided with a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafers W between the carriers C and the delivery unit 14 by using the wafer holding mechanism.

The processing station 3 is provided adjacent to the transfer section 12. The processing station 3 is equipped with a transfer section 15, a plurality of processing units 16, and tow reversers (REV) 20. The processing units 16 are arranged at both sides of the transfer section 15.

The transfer section 15 is provided with a substrate transfer device 17 therein. The substrate transfer device 17 is provided with a wafer holding mechanism configured to hold the wafer W. Further, the substrate transfer device 17 is movable horizontally and vertically and pivotable around a vertical axis, and serves to transfer the wafers W between the delivery unit 14 and the processing units 16 by using the wafer holding mechanism.

Each processing unit 16 is configured to perform a substrate processing on the wafer W transferred by the substrate transfer device 17. The processing unit 16 holds the transferred wafer and performs the substrate processing on the held wafer. The processing unit 16 performs the substrate processing by supplying a processing liquid onto the held wafer. The processing liquid may be, by way of non-limiting example, HF (hydrofluoric acid) or nitric acid (HNO₃). The processing liquid may be SC1 (a mixture of ammonia, hydrogen peroxide and water), or the like. The processing liquid may contain DIW (DeIonized Water). The processing liquid is selected according to the kind of a film to be etched on the wafer W.

Each reverser 20 is an inverting device configured to invert front and rear surfaces of the wafer W. As for the wafer W disposed in the reverser 20, one surface on which a pattern is formed and the other surface on which no pattern is formed are inverted.

Further, the substrate processing system 1 is provided with a control device 4. The control device 4 is, for example, a computer, and includes a controller 18 and a storage 19. The storage 19 stores a program that controls various processings performed in the substrate processing system 1. The controller 18 controls the operations of the substrate processing system 1 by reading and executing the program stored in the storage 19.

Further, the program may be recorded in a computer-readable recording medium, and installed from the recording medium to the storage 19 of the control device 4. The computer-readable recording medium may be, for example, a hard disc (HD), a flexible disc (FD), a compact disc (CD), a magnet optical disc (MO), or a memory card.

<Configuration of Processing Unit>

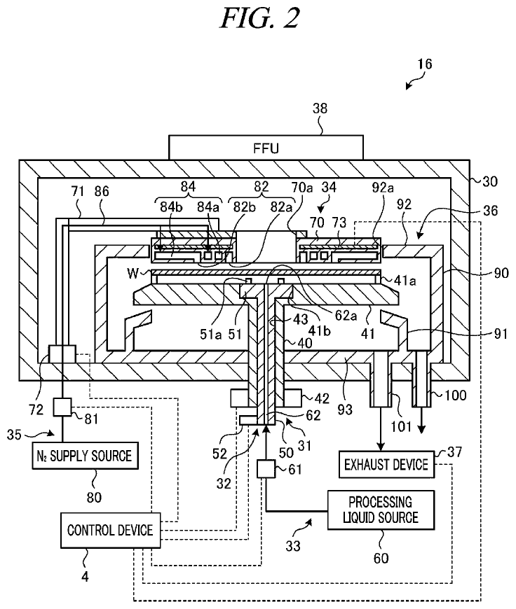

Now, a configuration of the processing unit 16 will be described with reference to FIG. 2. FIG. 2 is a schematic diagram illustrating a configuration of the processing unit 16 according to the first exemplary embodiment.

The processing unit 16 includes a chamber 30, a substrate holding mechanism 31, an elevating mechanism 32, a processing liquid supply mechanism 33, a heating mechanism 34, a gas supply mechanism 35, a recovery cup 36, and an exhaust device 37.

The chamber 30 accommodates therein a part of the substrate holding mechanism 31, a part of the processing liquid supply mechanism 33, and so forth. A FFU (Fan Filter Unit) 38 is provided at a ceiling of the chamber 30. The FFU 21 creates a downflow within the chamber 30.

The substrate holding mechanism 31 is equipped with a shaft member 40, a base plate 41, and a rotational driving unit 42. The shaft member 40 extends vertically. The shaft member 40 is formed to have a cylindrical shape.

The base plate 41 is provided on an upper end of the shaft member 40. The base plate 41 is of a circular shape. The base plate 41 has a diameter larger than that of the shaft member 40. The base plate 41 is formed to be concentric with the shaft member 40. A plurality of supporting pins 41a are provided on a top surface of the base plate 41. The plurality of supporting pins 41a are configured to be in contact with a bottom surface of the wafer W to support the wafer W. Further, the wafer W is supported by the support pins 41a such that the one surface thereof on which the pattern is formed faces down, that is, such that the one surface becomes the bottom surface.

A recess 41b is formed in a central portion of the top surface of the base plate 41. The recess 41b is of a circular shape on a cross section in a horizontal direction. An insertion hole 43 is formed in the base plate 41 and the shaft member 40 to be connected to a bottom surface of the recess 41b. A shaft 50 of the elevating mechanism 32 is inserted into the insertion hole 43.

The rotational driving unit 42 is configured to rotate the shaft member 40. The rotational driving unit 42 includes a deceleration mechanism, a motor, and so forth. As rotation of the motor is transmitted to the shaft member 40 via the deceleration mechanism or the like, the shaft member 40 is rotated. As the shaft member 40 is rotated, the base plate 41 and the wafer W are rotated.

As the downflow is created by the FFU 38 and the chamber 30 is evacuated by the exhaust device 37 to be described later, a negative pressure is generated between the bottom surface of the wafer W and the base plate 41. Accordingly, the wafer W is pressed against the supporting pins 41a, and the wafer W is held horizontally by the supporting pins 41a. As the shaft member 40 is rotated, the wafer W is rotated as one body with the substrate holding mechanism 31. That is, the substrate holding mechanism 31 (an example of a substrate holder) rotates the wafer W (an example of a substrate) while holding the wafer W horizontally.

In addition, a method of holding the wafer W in the substrate holding mechanism 31 is not limited to the above-described example. By way of example, the substrate holding mechanism 31 may hold the wafer W with a plurality of claws provided on the base plate 41. The plurality of claws are configured to hold a periphery of the wafer W.

The elevating mechanism 32 includes the shaft 50, a lift plate 51, and an elevational driving unit 52. The shaft 50 extends vertically. The shaft 50 is inserted into the insertion hole 43 formed in the substrate holding mechanism 31.

The lift plate 51 is provided on an upper end of the shaft 50. The lift plate 51 is of a circular shape. The lift plate 51 has a diameter larger than that of the shaft 50. Delivery pins 51a are provided on a top surface of the lift plate 51. The length of the delivery pin 51a is shorter than the length of the supporting pin 41a provided on the base plate 41.

The shaft 50 and the lift plate 51 are moved up and down between a lowered position and a raised position by the elevational driving unit 52. The lowered position is a preset position, and is a position at which the wafer W is subjected to a processing. At the lowered position, the lift plate 51 is accommodated in the recess 41b of the base plate 41. The raised position is a predetermined position, and is a position at which the wafer W is carried into or carried out of the chamber 30. At the raised position, the wafer W is positioned above the recovery cup 36.

A processing liquid supply line 62 of the processing liquid supply mechanism 33 is provided in the shaft 50 and the lift plate 51.

The elevational driving unit 52 includes a deceleration mechanism, a motor, and so forth. As rotation of the motor is transmitted to the shaft 50 via the deceleration mechanism or the like, the shaft 50 and the lift plate 51 are moved up and down. Further, the elevational driving unit 52 may be composed of a hydraulic pump, a hydraulic valve, a hydraulic cylinder, etc.

The processing liquid supply mechanism 33 includes a processing liquid source 60, a flow rate controller 61, and the processing liquid supply line 62. The processing liquid supply mechanism 33 is configured to supply the processing liquid to the wafer W from the processing liquid source 60. Further, the processing liquid supply mechanism 33 may supply a plurality of processing liquids to the wafer W. Specifically, the processing liquid supply mechanism 33 (an example of a processing liquid supply) supplies the processing liquid toward the one surface of the wafer W (the example of the substrate) held by the substrate holding mechanism 31 (the example of the substrate holder).

The flow rate controller 61 includes a flow rate control valve, an opening/closing valve, motors configured to operate the valves, and so forth. Further, the processing liquid supply mechanism 33 may include a heater configured to adjust the temperature of the processing liquid, a pump configured to force-feed the processing liquid, and so forth.

The processing liquid supply line 62 is provided in the shaft 50 and the lift plate 51 of the elevating mechanism 32. The processing liquid supply line 62 discharges the processing liquid toward the bottom surface (one surface) of the wafer W from a supply opening 62a formed at an upper end thereof.

The heating mechanism 34 includes a cover unit 70, an arm 71, and a moving mechanism 72. The cover unit 70 has an annular shape. The cover unit 70 is provided with an opening 70a. The opening 70a is formed at a central portion of the cover unit 70. The opening 70a is formed at a position corresponding to a central portion of the wafer W (the example of the substrate). The outer diameter of the cover unit 70 is substantially the same as the diameter of the wafer W. In addition, the opening 70a may be formed by punching.

The cover unit 70 is moved between a retreat position and a heating position by the moving mechanism 72 and the arm 71.

The retreat position is a preset position. Specifically, the retreat position is a position at which the cover unit 70 is not located above the wafer W, allowing the wafer W to be carried into the chamber 30 or carried out from the chamber 30. The heating position is a predetermined position. Specifically, the heating position is a position at which the cover unit 70 is located above the wafer W and a distance between the cover unit 70 and the wafer W is a certain heating distance. The cover unit 70 is configured to face a top surface (the other surface) of the wafer W opposite to the bottom surface (one surface) of the wafer W when it is located at the heating position.

The cover unit 70 includes a heater 73. The heater 73 is provided within the cover unit 70. The heater 73 is configured to heat the wafer W (the example of the substrate). The heater 73 is, for example, a sheath heater.

A reservoir 84 of the gas supply mechanism 35 is formed in the cover unit 70. A plurality of discharge openings 82 (an example of a gas supply opening) of the gas supply mechanism 35 are formed in a bottom surface of the cover unit 70.

The arm 71 is connected to the cover unit 70. The arm 71 is configured to allow the cover unit 70 to be moved between the retreat position and the heating position by the moving mechanism 72. The arm 71 is configured to be movable up and down and pivotable such that the cover unit 70 is movable between the retreat position and the heating position. Further, the cover unit 70 is not configured to be rotated with respect to the arm 71.

The moving mechanism 72 is configured to move the arm 71 such that the cover unit 70 is movable between the retreat position and the heating position. The moving mechanism 72 includes a deceleration mechanism, a motor, and so forth.

The gas supply mechanism 35 includes an N₂ gas source 80, a flow rate controller 81, the plurality of discharge openings 82, and the reservoir 84. The gas supply mechanism 35 is configured to supply the N₂ gas toward the top surface of the wafer W. The flow rate controller 81 includes a flow control valve, an opening/closing valve, motors configured to operate the valves, and so forth.

The plurality of discharge openings 82 are formed in the cover unit 70. The plurality of discharge openings 82 are configured to supply the N₂ gas (the example of the gas) toward the top surface (the other surface) of the wafer W (the example of the substrate) at an outer peripheral side than the opening 70a. The plurality of discharge openings 82 discharge the N₂ gas of the reservoir 84 toward the wafer W. Here, the outer peripheral side means an outer side in a diametrical direction of the wafer W.

The plurality of discharge openings 82 include a first discharge opening 82a (an example of a first gas supply opening) and a second discharge opening 82b (an example of a second gas supply opening).

The first discharge opening 82a is provided at a side of the opening 70a. The first discharge opening 82a is plural in number, and these first discharge openings 82a are formed at an equal distance therebetween along a circumferential direction of the cover unit 70, for example.

The second discharge opening 82b is provided at an outer peripheral side than the first discharge openings 82a. The second discharge opening 82b is plural in number, and these second discharge openings 82b are formed at an equal distance therebetween along the circumferential direction of the cover unit 70, for example.

The reservoir 84 is formed in the cover unit 70. The reservoir 84 is configured to store therein the N₂ gas (the example of the gas) supplied from the N₂ gas source 80 (an example of a gas source). The reservoir 84 includes a first reservoir 84a and a second reservoir 84b. The N₂ gas stored in the reservoir 84 is heated by the heater 73.

The first reservoir 84a is provided at a side of the opening 70a of the cover unit 70. The first reservoir 84a supplies the N₂ gas (the example of the gas) to the first discharge openings 82a (the example of the first gas supply opening). The N₂ gas is supplied into the first reservoir 84a from a gas supply path 86 connected to a top surface of the cover unit 70.

The first reservoir 84a is a curved gas flow path. For example, a part of the cover unit 70 serves as a wall between adjacent portions of the gas flow path. Due to the presence of the wall, a contact area between the N₂ gas of the first reservoir 84a and the cover unit 70 increases, so that a heating amount of the N₂ gas by the heater 73 increases.

The N₂ gas heated in the first reservoir 84a is discharged from the first discharge openings 82a toward the top surface (the other surface) of the wafer W.

The second reservoir 84b is provided at an outer peripheral side than the first reservoir 84a. Like the first reservoir 84a, the second reservoir 84b is a curved gas flow path. The second reservoir 84b supplies the N₂ gas (the example of the gas) to the second discharge openings 82b (the example of the second gas supply opening). The N₂ gas is supplied into the second storage unit 84b from the gas supply path 86.

The N₂ gas heated in the second reservoir 84b is discharged from the second discharge openings 82b toward the top surface (the other surface) of the wafer W.

The gas flow path of the first reservoir 84a and the gas flow path of the second reservoir 84b are set based on the heating amount of the N₂ gas in the reservoirs 84a and 84b, respectively. By setting the length of the gas flow path to be long, the heating amount in the heater 73 increases, so that the temperature of the N₂ gas increases. For example, by setting the lengths of the gas flow paths in the reservoirs 84a and 84b to be equal, the temperatures of the N₂ gases discharged from the discharge openings 82a and 82b toward the wafer W becomes equal.

The recovery cup 36 is configured to surround the base plate 41. The recovery cup 36 includes a first wall portion 90, a second wall portion 91, a ceiling portion 92, and a bottom portion 93. The first wall portion 90 is formed to have an annular shape. The first wall portion 90 is formed at an outer side than the base plate 41. The second wall portion 91 is formed to have an annular shape. The second wall portion 91 is formed at an inner side than the first wall portion 90. The second wall portion 91 is formed so that the processing liquid does not flow inwards over the second wall portion 91 but flows toward the outside of the second wall portion 91.

The ceiling portion 92 is formed to protrude inwards from an upper end of the first wall portion 90. The ceiling portion 92 is provided with an opening 92a. The opening 92a is of a circular shape. The opening 92a is formed to allow the wafer W and the cover unit 70 to be moved up and down therethrough.

A processing liquid drain pipe 100 and an exhaust pipe 101 are connected to the bottom portion 93. The processing liquid drain pipe 100 is connected to the bottom portion 93 at an outer side than the second wall portion 91. The processing liquid drain pipe 100 drains the processing liquid used for the processing of the wafer W to the outside.

The exhaust pipe 101 is connected to the bottom portion 93 at an inner side than the second wall portion 91. The exhaust pipe 101 is connected to the exhaust device 37. Here, a plurality of exhaust pipes 101 may be provided along the circumferential direction of the bottom portion 93 of the recovery cup 36. For example, the plurality of exhaust pipes 101 are arranged at an equal distance therebetween along the circumferential direction of the bottom portion 93.

The exhaust device 37 is configured to exhaust the gas within the chamber 30 to the outside through the exhaust pipe 101. The exhaust device 37 includes a pump or the like.

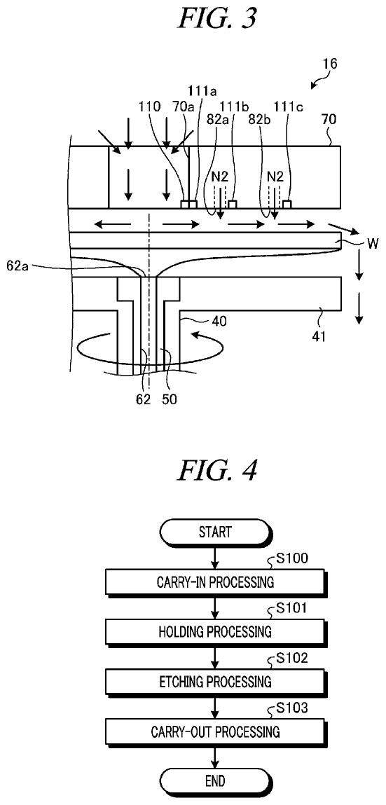

Further, as shown in FIG. 3, the processing unit 16 is equipped with a pressure sensor 110 and a plurality of temperature sensors 111a to 111c. FIG. 3 is a schematic diagram illustrating an arrangement of the pressure sensor 110 and the plurality of temperature sensors 111a to 111c in the processing unit 16 according to the present exemplary embodiment.

The pressure sensor 110 is provided at a lower end of the opening 70a of the cover unit 70. The pressure sensor 110 (an example of a sensor) is configured to detect an inflow state of a gas (fluid) from the opening 70a into a gap between the wafer W (the example of the substrate) and the cover unit 70. Specifically, the pressure sensor 110 detects the inflow state of the air into the gap formed between the wafer W and the cover unit 70 by detecting a pressure near the lower end of the opening 70a.

The plurality of temperature sensors 111a to 111c are, by way of example, infrared temperature sensors. The plurality of temperature sensors 111a to 111c are arranged along the diametrical direction of the cover unit 70. Each of the temperature sensors 111a to 111c is configured to detect the temperature of the processing liquid on the surface of the wafer W (the example of the substrate).

The temperature sensor 111a (hereinafter, referred to as “first temperature sensor 111a”) is provided near the opening 70a, and detects the temperature of the processing liquid on the bottom surface of the wafer W near the opening 70a.

The temperature sensor 111b (hereinafter, referred to as “second temperature sensor 111b”) is provided at an outer peripheral side of the cover unit 70 than the first temperature sensor 111a. Specifically, the second temperature sensor 111b detects the temperature of the processing liquid on the bottom surface of the wafer W near the first discharge openings 82a.

The temperature sensor 111c (hereinafter, referred to as “third temperature sensor 111c”) is provided at an outer peripheral side of the cover unit 70 than the second temperature sensor 111b. Specifically, the third temperature sensor 111c detects the temperature of the processing liquid on the bottom surface of the wafer W near the second discharge openings 82b.

Furthermore, each of the temperature sensors 111a to 111c may be plural in number, and the plurality of temperature sensors 111a (111b, 111c) may be arranged along the circumferential direction of the cover unit 70.

<Flows of Gas and Processing Liquid>

Now, a flow of the gas and a flow of the processing liquid in the processing unit 16 according to the first exemplary embodiment will be discussed.

In the processing unit 16, a film residue of the wafer W and a reaction product may adhere to the wafer W as particles when etching by the processing liquid is performed. In addition, there is a risk that the generated particles may whirl up by vibration of the processing unit 16 or the flow of the gas, ending up being attached to the wafer W. As a way to suppress this problem, the downflow is formed by the FFU 38 in the processing unit 16 to suppress the particles from adhering to the wafer W. Further, the gas in the chamber 30 is exhausted by the exhaust device 37.

As the downflow is formed, there is a concern that the temperature of the wafer W may be reduced. Further, as the wafer W is rotated during the processing, a swirling flow is generated, and the gas flows from the center of the wafer W toward the outer periphery thereof. Accordingly, the temperature of the outer periphery of the wafer W is lower than that of the center of the wafer W.

Furthermore, since the processing liquid is discharged from the supply opening 62a of the processing liquid supply line 62 to the center of the wafer W to be diffused to the outer periphery of the wafer W by the rotation of the wafer W, the temperature of the outer periphery of the wafer W becomes lower than the temperature of the center of the wafer W. For this reason, a temperature difference is generated between the center of the wafer W and the outer periphery of the wafer W. If this temperature difference increases, there may be generated a difference in a processing reaction rate by the processing liquid, resulting in non-uniformity of the etching.

In the processing unit 16, the cover unit 70 is disposed above the wafer W. Accordingly, the whirl-up of the particles is suppressed. In addition, since the swirling flow generated by the rotation of the wafer W flows through the gap formed between the top surface of the wafer W and the cover unit 70, the particles are discharged to the outer side than the wafer W.

Since the opening 70a is provided in the central portion of the cover unit 70, the air is introduced toward the central portion of the wafer W through the opening 70a, and a stable swirling flow flows through the gap formed between the upper surface of the wafer W and the cover unit 70. In addition, since the opening 70a is provided in the central portion of the cover unit 70, an increase of a negative pressure on the top surface of the wafer W is suppressed. Accordingly, the central portion of the wafer W is suppressed from being curved so as to protrude upwards due to the negative pressure, so that the contact between the cover unit 70 and the wafer W is suppressed.

In the processing unit 16, the wafer W is heated by the heater 73 provided in the cover unit 70. Since the opening 70a is formed in the cover unit 70, the heater 73 is not provided in the central portion of the cover unit 70. Since the processing liquid is discharged from the bottom surface side of the wafer W to the central portion of the wafer W facing the opening 70a of the cover unit 70, the central portion of the wafer W has a temperature suitable for the etching by the processing liquid.

Further, the processing unit 16 discharges the N₂ gas heated by the heater 73 in the first reservoir 84a provided in the cover unit 70 toward the top surface of the wafer W from the first discharge openings 82a. Further, the processing unit 16 discharges the N₂ gas heated by the heater 73 in the second reservoir 84b provided in the cover unit 70 toward the top surface of the wafer W from the second discharge openings 82b.

The N₂ gas discharged from the first discharge openings 82a and the second discharge openings 82b is made to flow toward the outer periphery of the wafer W along the top surface of the wafer W by the rotation of the wafer W. The N₂ gas discharged from the first discharge openings 82a and the second discharge openings 82b heats the wafer W.

As the N₂ gas discharged from the first discharge openings 82a and the second discharge openings 82b flows toward the outer periphery of the wafer W, the inflow of the air from the opening 70a into the gap between the top surface of the wafer W and the cover unit 70 is accelerated.

Therefore, even when the rotation speed of the wafer W is set to be low so that the swirling flow generated by the rotation of the wafer W is thus small, the inflow of the air from the opening 70a into the gap between the top surface of the wafer W and the cover unit 70 is still accelerated, so that stay of the air in the gap is suppressed.

<Substrate Processing>

Now, a substrate processing according to the first exemplary embodiment will be described with reference to FIG. 4. FIG. 4 is a flowchart for describing the substrate processing according to the first exemplary embodiment.

The control device 4 performs a carry-in processing for the wafer W (S100). Specifically, the wafer W is carried into the chamber 30 by the transfer section 15. Then, the wafer W is transferred from the transfer section 15 to the lift plate 51 which is placed at the raised position. Further, the cover unit 70 is kept at the retreat position.

After the wafer W is transferred onto the lift plate 51, the lift plate 51 is lowered to the lowered position. Accordingly, the wafer W is transferred from the lift plate 51 onto the base plate 41.

Further, the cover unit 70 is moved from the retreat position to the heating position. Accordingly, the cover unit 70 is placed above the top surface of the wafer W.

The control device 4 performs a holding processing for the wafer W (S101). The air in the chamber 30 is exhausted to the outside by the exhaust device 37. As a result, the negative pressure is generated on the bottom surface of the wafer W, and the wafer W is pressed against the supporting pins 41a of the base plate 41 to be held by the base plate 41.

The control device 4 performs an etching processing for the wafer W (S102). The heating of the wafer W by the heater 73 is started, and the supply of the N₂ gas is begun. The N₂ gas is stored in the reservoir 84 from the N₂ gas source 80 and heated by the heater 73. Thus, the heated N₂ gas is discharged toward the top surface of the wafer W from the first discharge openings 82a and the second discharge openings 82b. The supply amount of the N₂ gas is adjusted based on the rotation speed of the wafer W. For example, with a rise of the rotation speed of the wafer W, the supply amount of the N₂ gas per unit time increases.

Further, the shaft member 40 of the substrate holding mechanism 31 is rotated by the rotation driving unit 42, and the wafer W is rotated along with the shaft member 40 and the base plate 41. Further, the processing liquid is supplied toward the bottom surface of the wafer W by the processing liquid supply mechanism 33, and the etching on the bottom surface of the wafer W is begun.

The control device 4 controls the flow rate of the N₂ gas (the example of the gas) based on the rotation speed of the wafer W (the example of the substrate). To elaborate, the control device 4 controls the flow rate of the N₂ gas (the example of the gas) based on the flow rate of the processing liquid, the temperature of the processing liquid, and the rotation speed of the wafer W. For example, a relationship between the flow rate of the processing liquid, the temperature of the processing liquid, the rotation speed of the wafer W, and the flow rate of the N₂ gas is obtained by an experiment or a simulation, and stored in the storage 19 as a data table. Then, in order to perform the etching processing, the flow rate of the processing liquid, the temperature of the processing liquid and the rotation speed of the wafer W are set, and the flow rate of the N₂ gas corresponding to each set value is calculated. Then, the flow rate of the N₂ gas is controlled to the calculated flow rate. Further, the data table is set for each kind of the processing liquid. Instead of the data table, the control device 4 may store, in the storage 19, a relational model between the flow rate of the processing liquid, the temperature of the processing liquid, the rotation speed of the wafer W, and the flow rate of the N₂ gas.

In addition, the control device 4 controls the temperature of the heater 73 based on the flow rate of the processing liquid, the temperature of the processing liquid, and the rotation speed of the wafer W. For example, a relationship between the flow rate of the processing liquid, the temperature of the processing liquid, the rotation speed of the wafer W, and the temperature of the N₂ gas is obtained by an experiment or a simulation, and stored in the storage 19 as a data table. Then, in order to perform the etching processing, the flow rate of the processing liquid, the temperature of the processing liquid, and the rotation speed of the wafer W are set, and the temperature of the N₂ gas corresponding to each set value is calculated. Then, the heater 73 is controlled such that the temperature of the N₂ gas reaches the calculated temperature. The data table is set for each type of the processing liquid. Instead of the data table, the control device 4 may store, in the storage 19, a relational model between the flow rate of the processing liquid, the temperature of the processing liquid, the rotation speed of the wafer W, and the temperature of the N₂ gas.

The control device 4 performs a carry-out processing for the wafer W (S103). Upon the completion of the etching processing, the heating by the heater 73, the supply of the N₂ gas, and the supply of the processing liquid are ended. Further, the exhaust of the gas by the exhaust device 37 is also finished. Then, the cover unit 70 is moved from the heating position to the retreat position. After the cover unit 70 is moved to the retreat position, the lift plate 51 is moved from the lowered position to the raised position. Accordingly, the wafer W is transferred from the substrate holding mechanism 31 to the lift plate 51, and is then raised. Thereafter, the wafer W is transferred from the lift plate 51 to the transfer section 15, and is carried out from the chamber 30 by the transfer section 15.

<Abnormality Determination Processing>

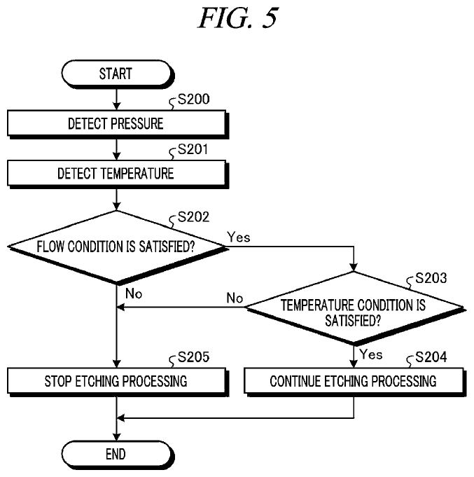

Next, an abnormality determination processing according to the first exemplary embodiment will be described with reference to FIG. 5. The abnormality determination processing is performed during the etching processing.

The control device 4 detects the pressure near the opening 70a of the cover unit 70 by the pressure sensor 110 (S200). The control device 4 detects the temperature of the processing liquid on the bottom surface of the wafer W by the respective temperature sensors 111a to 111c (S201).

The control device 4 determines whether or not the inflow state of the gas from the opening 70a into the gap between the wafer W and the cover unit 70 satisfies a given flow condition (S202). Specifically, when the detected pressure is equal to or less than a given pressure, the control device 4 makes a determination that the inflow state satisfies the given flow condition. If the detected pressure is larger than the given pressure, on the other hand, the control device 4 makes a determination that the inflow state does not satisfy the given flow condition. The given pressure is a predetermined pressure and is a negative pressure.

When the flow rate of the N₂ gas discharged from the first discharge openings 82a or the second discharge openings 82b increases, there is a likelihood that the flow of the gas from the center of the wafer W toward the outer periphery thereof may be obstructed. When the gas flows from the center of the wafer W toward the outer periphery thereof in the gap between the wafer W and the cover unit 70, the pressure near the opening 70a becomes a negative pressure. Meanwhile, when the gas does not flow from the center of the wafer W toward the outer periphery thereof in the gap between the wafer W and the cover unit 70 as the flow of the gas from the center toward the outer periphery of the wafer W is obstructed, the pressure near the opening 70a becomes an exterior air pressure or a positive pressure.

When the detected pressure is equal to or less than the given pressure, the control device 4 makes a determination that the flow of the gas from the center of the wafer W toward the outer periphery thereof is not obstructed and the inflow state satisfies the given flow condition.

When the detected pressure is larger than the given pressure, the control device 4 makes a determination that the flow of the gas from the center of the wafer W toward the outer periphery thereof is obstructed and the inflow state does not satisfy the given flow condition.

When the inflow state satisfies the given flow condition (S202: Yes), the control device 4 determines whether the temperature of the processing liquid on the bottom surface of the wafer W meets a given temperature condition (S203). To elaborate, when a temperature difference between the highest temperature and the lowest temperature among the detected temperatures is equal to or less than a given temperature difference, the control device 4 makes a determination that the temperature of the processing liquid satisfies the given temperature condition. When the temperature difference is larger than the given temperature difference, on the other than, the control device 4 makes a determination that the temperature of the processing liquid does not satisfy the given temperature condition. The given temperature difference is a preset temperature difference, and is a temperature difference at which the non-uniformity of the etching in the wafer W is suppressed. That is, the given temperature difference is a temperature difference allowing the in-surface uniformity of the etching in the wafer W to be maintained at a preset uniformity level.

When the temperature difference is equal to or less than the given temperature difference, the control device 4 makes a determination that the temperature of the processing liquid satisfies the given temperature condition so that the degree of non-uniformity of the etching is low. When the temperature difference is larger than the given temperature difference, on the other hand, the control device 4 makes a determination that the temperature of the processing liquid does not satisfy the given temperature condition so that the degree of non-uniformity of the etching is high.

When the temperature of the processing liquid satisfies the given temperature condition (S203: Yes), the control device 4 carries on the etching processing (S204). That is, the control device 4 continues the etching processing when the inflow state satisfies the given flow condition (S202: Yes) and the temperature of the processing liquid satisfies the given temperature condition (S203: No) (S204).

When the inflow state does not satisfy the given flow condition (S202: No), the control device 4 stops the etching processing (S205). That is, when the inflow state does not satisfy the given flow condition, the control device 4 stops the etching processing (an example of a processing) on the wafer W (the example of the substrate).

When the temperature of the processing liquid does not satisfy the given temperature condition (S203: No), the control device 4 stops the etching processing (S205). That is, when the processing liquid does not satisfy the given temperature condition, the control device 4 stops the etching processing (the example of the processing) on the wafer W (the example of the substrate).

<Effects>

The substrate processing system 1 (the example of the substrate processing apparatus) includes the substrate holding mechanism 31 (the example of the substrate holder), the processing liquid supply mechanism 33 (the example of the processing liquid supply), and the cover unit 70. The substrate holding mechanism 31 rotates the wafer W while holding the wafer W (the example of the substrate) horizontally. The processing liquid supply mechanism 33 supplies the processing liquid toward the bottom surface (one surface) of the wafer W held by the substrate holding mechanism 31. The cover unit 70 is configured to face the top surface (the other surface) of the wafer W opposite to the bottom surface. The cover unit 70 is provided with the heater 73 which is configured to heat the wafer W. The cover unit 70 is provided with the opening 70a and the plurality of discharge openings 82 (the example of the gas supply opening). The opening 70a is formed at the position corresponding to the central portion of the wafer W. The plurality of discharge openings 82 supply the N₂ gas (the example of the gas) toward the top surface of the wafer W at the outer peripheral side than the opening 70a. The N₂ gas is heated by the heater 73. The supply amount of the N₂ gas is adjusted based on the rotation speed of the wafer W.

With this configuration, the substrate processing system 1 is capable of supplying the N₂ gas heated by the heater 73 toward the wafer W, and is capable of heating the wafer W by the N₂ gas. Since the supply amount of the N₂ gas is adjusted based on the rotation speed of the wafer W, the obstruction of the inflow of the gas from the opening 70a into the gap between the wafer W and the cover unit 70 due to the supply of the N₂ gas is suppressed. Thus, the supplied N₂ gas flows from the center of the wafer W toward the outer periphery thereof, so that the decrease in the temperature of the outer periphery of the wafer W is suppressed. Therefore, the substrate processing system 1 is capable of improving the in-surface uniformity of the temperature of the wafer W, thus capable of suppressing the non-uniformity of the etching in the wafer W.

The cover unit 70 has the reservoir 84. The reservoir 84 stores therein the gas supplied from the N₂ gas source 80 (the example of the gas source).

With this configuration, the substrate processing system 1 is capable of heating the N₂ gas stored in the cover unit 70 by the heater 73. Accordingly, the substrate processing system 1 is capable of supplying the N₂ gas with the stable temperature to the wafer W, and is thus capable of stabilizing the temperature of the wafer W. Therefore, the substrate processing system 1 is capable of suppressing the non-uniformity of the etching. In the substrate processing system 1, even when the number of wafers W processed per hour is increased, the temperature of the wafer W can be stabilized by heating the N₂ gas through the reservoir 84, so that the processing efficiency can be improved.

The plurality of discharge openings 82 (the example of the gas supply opening) include the first discharge openings 82a (the example of the first gas supply opening) and the second discharge openings 82b (the example of the second gas supply opening). The first discharge openings 82a are provided near the opening 70a. The second discharge openings 82b are provided at the outer peripheral side than the first discharge openings 82a. The reservoir 84 includes the first reservoir 84a and the second reservoir 84b. The first reservoir 84a is provided near the opening 70a to supply the N₂ gas to the first discharge openings 82a. The second reservoir 84b is provided at the outer peripheral side than the first reservoir 84a to supply the N₂ gas to the second discharge openings 82b.

With this configuration, the substrate processing system 1 is capable of supplying the N₂ gas to the wafer W from the different discharge openings 82a and 82b in the diametrical direction of the wafer W, so that the temperature difference in the wafer W in the diametrical direction can be reduced. Thus, in the substrate processing system 1, the in-surface uniformity of the temperature of the wafer W can be improved, so that the non-uniformity of the etching in the wafer W can be suppressed.

The first reservoir 84a and the second reservoir 84b are curved gas flow paths.

With this configuration, the substrate processing system 1 can increase the heating amount of the N₂ gas by the heater 73 in the first reservoir 84a and the second reservoir 84b, so that the temperature of the N₂ gas supplied to the wafer W from the first and second discharge openings 82a and 82b can be increased.

The substrate processing system 1 (the example of the substrate processing apparatus) is equipped with the control device 4. The control device 4 controls the flow rate of the N₂ gas (the example of the gas) based on the rotation speed of the wafer W (the example of the substrate).

Thus, the substrate processing system 1 is capable of adjusting the heating amount of the wafer W by the N₂ gas with respect to the rotation speed of the wafer W. Therefore, the substrate processing system 1 is capable of stabilizing the temperature of the wafer W and suppressing the non-uniformity of the etching in the wafer W.

The control device 4 controls the flow rate of the gas based on the flow rate of the processing liquid, the temperature of the processing liquid, and the rotation speed of the wafer W (the example of the substrate).

Thus, the substrate processing system 1 is capable of stabilizing the temperature of the wafer W and suppressing the non-uniformity of the etching in the wafer W.

The control device 4 controls the temperature of the heater 73 based on the flow rate of the processing liquid, the temperature of the processing liquid, and the rotation speed of the substrate.

Thus, the substrate processing system 1 is capable of stabilizing the temperature of the wafer W, and is thus capable of suppressing the non-uniformity of the etching in the wafer W.

The substrate processing system 1 (the example of the substrate processing apparatus) includes the pressure sensor 110. The pressure sensor 110 detects the inflow state of the gas into the gap between the wafer W (the example of the substrate) and the cover unit 70 from the opening 70a. The control device 4 stops the etching processing (the example of the processing) on the wafer W when the inflow state does not satisfy the given flow condition.

Thus, the substrate processing system 1 is capable of stopping the etching processing when the abnormality occurs in the inflow of the gas into the gap between the wafer W and the cover unit 70.

The substrate processing system 1 (the example of the substrate processing apparatus) includes the plurality of temperature sensors 111a to 111c. The plurality of temperature sensors 111a to 111c detect the temperature of the processing liquid on the bottom surface (one surface) of the wafer W (the example of the substrate). The control device 4 stops the etching processing (the example of the processing) on the wafer W when the temperature of the process liquid does not satisfy the given temperature condition.

With this configuration, the substrate processing system 1 is capable of stopping the etching processing when the abnormality occurs in the temperature of the wafer W estimated by the temperature of the processing liquid.

### Second Exemplary Embodiment

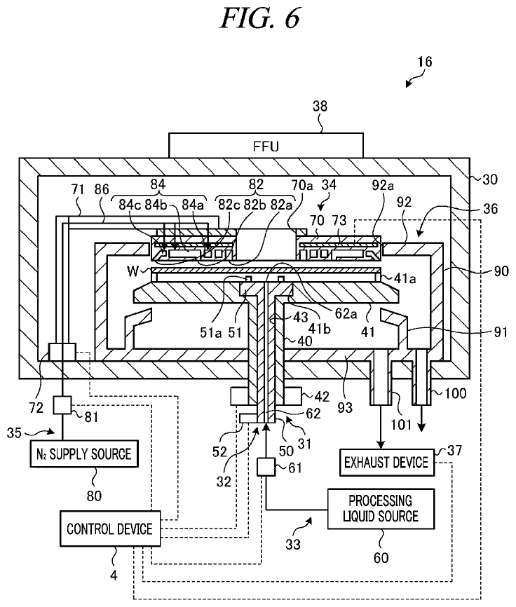

Now, a processing unit 16 according to a second exemplary embodiment will be described with reference to FIG. 6. FIG. 6 is a schematic diagram illustrating a configuration of the processing unit 16 according to the second exemplary embodiment. Here, parts different from those of the first exemplary embodiment will be explained, whereas parts identical to those of the first exemplary embodiments will be assigned same reference numerals, and redundant description will be omitted.

The plurality of discharge openings formed in the cover unit 70 include, in addition to the first discharge openings 82a and the second discharge openings 82b, a third discharge opening 82c (an example of a third gas supply opening).

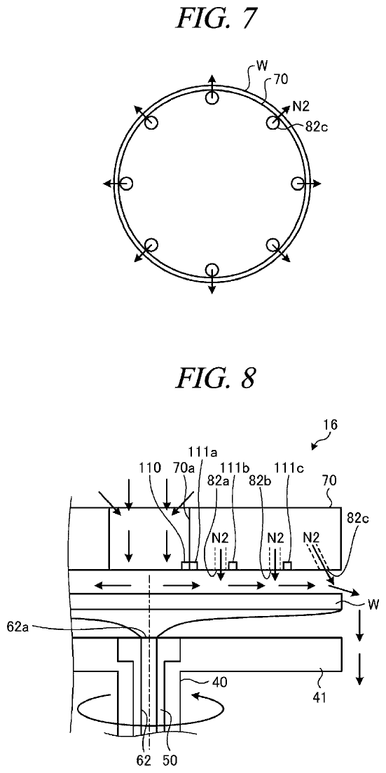

The third discharge opening 82c is provided at an outer peripheral side than the second discharge openings 82b. The third discharge opening 82c is plural in number. These third discharge openings 82c are formed while being space apart from each other at an equal distance along the circumferential direction of the cover unit 70, for example. The third discharge openings 82c supply the N₂ gas (the example of the gas) toward an end portion of the wafer W (the example of the substrate) in an inclined direction. The inclined direction is a direction inclined from the inside to the outside in the diametrical direction of the wafer W, as shown in FIG. 7. That is, the third discharge openings 82c are configured to discharge the N₂ gas from the inside to the outside in the diametrical direction of the wafer W. FIG. 7 is a diagram illustrating a supply direction (discharge direction) of the N₂ gas discharged from the third discharge openings 82c according to the second exemplary embodiment.

A supply amount of the N₂ gas supplied from the third discharge openings 82c is set regardless of the rotation speed of the wafer W. For example, the supply amount of the N₂ gas supplied from the third discharge openings 82c is a predetermined amount. The supply amount of the N₂ gas supplied from the third discharge openings 82c may be adjusted based on the rotation speed of the wafer W. That is, the supply amount of at least some of the N₂ gas discharged from the plurality of discharge openings 82 is adjusted based on the rotation speed of the wafer W.

Referring back to FIG. 6, the reservoir 84 formed in the cover unit 70 includes a third reservoir 84c in addition to the first reservoir 84a and the second reservoir 84b.

The third reservoir 84c is provided at an outer peripheral side than the second reservoir 84b. The third reservoir 84c is a curved gas flow path, the same as the first reservoir 84a and the second reservoir 84b. The third reservoir 84c supplies the N₂ gas (the example of the gas) to the third discharge openings 82c (the example of the third gas supply opening). The N₂ gas is supplied into the third reservoir 84c from the gas supply path 86. The N₂ gas (the example of the gas) stored in the third reservoir 84c is heated by the heater 73.

The N₂ gas heated in the third reservoir 84c is discharged from the third discharge openings 82c toward the top surface (the other surface) of the wafer W. The gas flow path of the third reservoir 84c is set according to the heating amount of the N₂ gas in the third reservoir 84c. For example, by setting the length of the gas flow path in each of the reservoirs 84a to 84c to be equal, the temperature of the N₂ gas discharged from each of the discharge openings 82a to 82c toward the wafer W becomes equal.

In the processing unit 16, since the N₂ gas is discharged from the third discharge openings 82c toward the end portion of the wafer W in the inclined direction, as shown in FIG. 8, the processing gas can be suppressed from being flown to the top surface of the wafer W. FIG. 8 is a schematic diagram illustrating flow of the processing liquid and the N₂ gas in the processing unit 16 according to the second exemplary embodiment.

In the substrate processing system 1, the plurality of discharge openings 82 (the example of the gas supply opening) includes the third discharge openings 82c (the example of the third gas supply opening). The third discharge openings 82c are provided at the outer peripheral side than the second discharge openings 82b (the example of the second gas supply opening).

Thus, due to the N₂ gas discharged from the third discharge openings 82c, the substrate processing system 1 is capable of suppressing the processing liquid from reaching the top surface of the wafer W.

The third discharge openings 82c supply the N₂ gas (the example of the gas) in the inclined direction toward the end portion of the wafer W. The inclined direction is the direction inclined from the inside to the outside in the diametrical direction of the wafer W.

Thus, due to the N2 gas discharged from the third discharge openings 82c, the substrate processing system 1 is capable of suppressing the processing liquid from reaching the top surface of the wafer W.

The reservoir 84 includes a third reservoir 84c. The third reservoir 84c is provided at the outer peripheral side than the second reservoir 84b, and supplies the N₂ gas to the third discharge openings 82c. The N₂ gas stored in the third reservoir 84c is heated by the heater 73.

With this configuration, the substrate processing system 1 is capable of heating the N₂ gas supplied from the third discharge openings 82c toward the wafer W, thus capable of suppressing the decrease in the temperature of the end portion of the wafer W. The substrate processing system 1 is capable reducing the temperature difference in the diametrical direction of the wafer W. Hence, the substrate processing system 1 is capable of improving the in-surface uniformity of the temperature of the wafer W, and is thus capable of suppressing the non-uniformity of the etching in the wafer W.

The third reservoir 84c is the curved gas flow path.

With this configuration, the substrate processing system 1 is capable of increasing the heating amount of the N₂ gas by the heater 73 in the third storage 84c, so that the temperature of the N₂ gas supplied to the wafer W from the third discharge openings 82c can be increased.

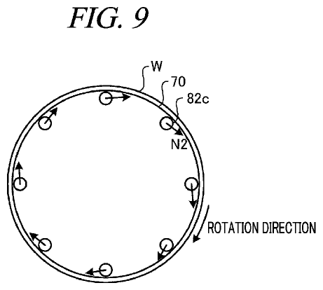

In addition, the inclined direction in which the N₂ gas (the example of the gas) is supplied from the third discharge openings 82c (the example of the third gas supply opening) may be a direction inclined toward a rotation direction of the wafer W, as shown in FIG. 9. That is, the third discharge openings 82c are configured to discharge the N₂ gas along the rotation direction of the wafer W. FIG. 9 is a diagram illustrating a supply direction (discharge direction) of the N₂ gas discharged from the third discharge openings 82c according to a modification example of the second exemplary embodiment.

Thus, due to the N₂ gas discharged from the third discharge openings 82c, the substrate processing system 1 is capable of suppressing the processing liquid from reaching the top surface of the wafer W.

Furthermore, the second reservoir 84b may be used as the third reservoir 84b as well. That is, the second reservoir 84b supplies the N₂ gas (the example of the gas) to the third discharge openings 82c (the example of the third gas supply opening).

Thus, in the substrate processing system 1, the configuration of the reservoir 84 formed in the cover unit 70 can be simplified.

### MODIFICATION EXAMPLES

In the cover unit 70 of the substrate processing system 1 according to a modification example, the heater 73 may be provided closer to the wafer W (the example of the substrate) than the reservoir 84 is. That is, the reservoir 84 may be formed above the heater 73. With this configuration, in the substrate processing apparatus according to the modification example, the non-uniformity in the heating of the wafer W by the heater 73 can be reduced. The reservoir 84 is formed at least either above or below the heater 73.

In the substrate processing system 1 according to the modification example, the reservoir 84 may be formed above and below the heater 73. The N₂ gas is supplied from the N₂ gas source 80 into the reservoir 84 formed above the heater 73. Then, the N₂ gas is supplied from the reservoir 84 formed above the heater 73 into the reservoir 84 formed below the heater 73, and then supplied from the reservoir formed below the heater 73 toward the wafer W. In the configuration in which the reservoir 84 is formed above and below the heater 73, the N₂ gas is pre-heated by the reservoir 84 formed above the heater 73. Thus, in the substrate processing system 1 according to the modification example, a discharge of the N₂ gas with a low temperature toward the wafer W can be suppressed. Furthermore, in the substrate processing system 1 according to the modification, it is possible to suppress the decrease in the temperature of the N₂ gas even when the number of wafers W processed increases. Thus, in the substrate processing system 1 according to the modification example, the processing efficiency of the wafer W can be improved.

In the cover unit 70 of the substrate processing system 1 according to the modification example, the N₂ gas may be discharged toward the top surface of the wafer W by a nozzle.

The cover unit 70 of the substrate processing system 1 according to the modification example may discharge the N₂ gas in an inclined direction with respect to the wafer W.

By way of example, the first discharge openings 82a and the second discharge openings 82b may discharge the N₂ gas obliquely downwards toward the outer periphery of the wafer W. Thus, in the substrate processing system 1 according to the modification example, it is possible to suppress the N₂ gas from staying in the gap between the wafer W and the cover unit 70.

As another example, the first discharge openings 82a and the second discharge openings 82b may discharge the N₂ gas obliquely downwards toward the center of the wafer W. Thus, in the substrate processing system 1 according to the modification example, the time during which the N₂ gas exists between the wafer W and the cover unit 70 can be lengthened, so that the flow rate of the N₂ gas used to heat the wafer W can be reduced.

In addition, the N₂ gas may be supplied to the reservoir 84 of the cover unit 70 when the etching processing is not being performed. In this case, the flow rate of the N2 gas is smaller, as compared to the flow rate of the N₂ gas supplied during the etching processing.

In the substrate processing system 1 according to the modification example, the flow rates of the N₂ gas discharged from the first discharge openings 82a and the second discharge openings 82b per unit time may be set to be different.

By way of example, the flow rate of the N₂ gas discharged from the first discharge openings 82a per unit time is larger than the flow rate of the N₂ gas discharged from the second discharge openings 82b per unit time. Thus, in the substrate processing system 1 according to the modification example, the wafer W can be heated by the N₂ gas discharged from the first discharge openings 82a having a long distance to the outer periphery of the wafer W, the in-surface uniformity of the temperature of the entire wafer W can be improved.

As another example, the flow rate of the N₂ gas discharged from the second discharge openings 82b per unit time may be set to be larger than the flow rate of the N₂ gas discharged from the first discharge openings 82a. Thus, in the substrate processing system 1 according to the modification example, the etching on the outer periphery of the wafer W can be accelerated.

It should be noted that the above-described exemplary embodiment is illustrative in all aspects and is not anyway limiting. The above-described exemplary embodiment may be omitted, replaced and modified in various ways without departing from the scope and the spirit of claims.

According to the exemplary embodiment, it is possible to improve the in-surface uniformity of the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a substrate holder configured to hold a substrate horizontally and rotate the substrate;
a processing liquid supply configured to supply a processing liquid toward a first surface of the substrate held by the substrate holder; and
a cover unit configured to face a second surface of the substrate, the second surface being opposite to the first surface,
wherein the cover unit comprises a heater configured to heat the substrate,
the cover unit is provided with an opening at a position corresponding to a central portion of the substrate,
the cover unit is also provided with, at an outer peripheral side than the opening, multiple gas supply openings through which a gas is supplied toward the second surface of the substrate,
the gas is heated by the heater, and
a supply amount of at least some of the gas is adjusted based on a rotation speed of the substrate.

2. The substrate processing apparatus of claim 1,
wherein the cover unit is provided with a reservoir in which the gas supplied from a gas source is stored,
the reservoir is formed at least either above or below the heater, and
the gas stored in the reservoir is heated by the heater.

3. The substrate processing apparatus of claim 2,
wherein the multiple gas supply openings include:
a first gas supply opening provided near the opening; and
a second gas supply opening provided at an outer peripheral side than the first gas supply opening, and
wherein the reservoir includes:
a first reservoir provided near the opening, and configured to supply the gas to the first gas supply opening; and
a second reservoir provided at an outer peripheral side than the first reservoir, and configured to supply the gas into the second gas supply opening.

4. The substrate processing apparatus of claim 3,
wherein the first reservoir and the second reservoir are curved gas flow paths.

5. The substrate processing apparatus of claim 4,
wherein the multiple gas supply openings include a third gas supply opening provided at an outer peripheral side than the second gas supply opening.

6. The substrate processing apparatus of claim 5,
wherein the third gas supply opening is configured to supply the gas toward an end portion of the substrate in an inclined direction, and
the inclined direction is a direction inclined from an inside to an outside in a diametrical direction of the substrate.

7. The substrate processing apparatus of claim 5,
wherein the third gas supply opening is configured to supply the gas toward an end portion of the substrate in an inclined direction, and
the inclined direction is a direction inclined toward a rotation direction of the substrate.

8. The substrate processing apparatus of claim 5,
wherein the reservoir further includes a third reservoir provided at an outer peripheral side than the second reservoir, and configured to supply the gas to the third gas supply opening, and
the gas stored in the third reservoir is heated by the heater.

9. The substrate processing apparatus of claim 8,
wherein the third reservoir is a curved gas flow path.

10. The substrate processing apparatus of claim 5,
wherein the second reservoir is configured to supply the gas to the third gas supply opening.

11. The substrate processing apparatus of claim 3,
wherein the multiple gas supply openings include a third gas supply opening provided at an outer peripheral side than the second gas supply opening.

12. The substrate processing apparatus of claim 11,
wherein the third gas supply opening is configured to supply the gas toward an end portion of the substrate in an inclined direction, and
the inclined direction is a direction inclined from an inside to an outside in a diametrical direction of the substrate.

13. The substrate processing apparatus of claim 11,
wherein the third gas supply opening is configured to supply the gas toward an end portion of the substrate in an inclined direction, and
the inclined direction is a direction inclined toward a rotation direction of the substrate.

14. The substrate processing apparatus of claim 1, further comprising:
a control device configured to control a flow rate of the gas based on the rotation speed of the substrate.

15. The substrate processing apparatus of claim 14,
wherein the control device is configured to control the flow rate of the gas based on a flow rate of the processing liquid, a temperature of the processing liquid, and the rotation speed of the substrate.

16. The substrate processing apparatus of claim 14,
wherein the control device is configured to control a temperature of the heater based on a flow rate of the processing liquid, a temperature of the processing liquid, and the rotation speed of the substrate.

17. The substrate processing apparatus of claim 14, further comprising:
a sensor configured to detect an inflow state of the gas from the opening into a gap between the substrate and the cover unit,
wherein the control device is configured to stop a processing on the substrate when the inflow state does not satisfy a given flow condition.

18. The substrate processing apparatus of claim 14, further comprising:
multiple temperature sensors each configured to detect a temperature of the processing liquid on a surface of the substrate,
wherein the control device is configured to stop a processing on the substrate when the temperature of the processing liquid does not satisfy a given temperature condition.

19. The substrate processing apparatus of claim 15,
wherein the control device is configured to control a temperature of the heater based on the flow rate of the processing liquid, the temperature of the processing liquid, and the rotation speed of the substrate.

20. A substrate processing method, comprising:
supplying a processing liquid toward a first surface of a substrate held and rotated by a substrate holder;
heating the substrate by a heater of a cover unit configured to face a second surface of the substrate, the second surface being opposite to the first surface; and
supplying a gas toward the second surface of the substrate from a gas supply opening provided at an outer peripheral side than an opening of the cover unit,
wherein the gas is heated by the heater, and
a supply amount of the gas is adjusted based on a rotation speed of the substrate.
